(19) United States
(12) Patent Application Publication
(10) Pub. No.: US 2026/0190713 A1
(43) Pub. Date: Jul. 2, 2026

(54) DISPLAY PANEL AND ELECTRONIC APPARATUS INCLUDING THE SAME

(71) Applicant: Samsung Display Co., Ltd., Yongin-si (KR)

(72) Inventors: Arong Kim, Yongin-si (KR); Youngmin Moon, Yongin-si (KR); Samin Lee, Yongin-si (KR)

(21) Appl. No.: 19/429,820

(22) Filed: Dec. 22, 2025

(30) Foreign Application Priority Data
Dec. 27, 2024 (KR) 10-2024-0199337

(51) Int. Cl. H10K 59/131; H10K 59/12; H10K 59/124

(52) U.S. Cl. CPC H10K 59/131; H10K 59/1201; H10K 59/124

(57) ABSTRACT

A display panel includes a substrate, a planarization layer above the substrate, a support layer above the planarization layer, and having an isolated shape in plan view, a patterning wire above the planarization layer, and contacting a side surface of the support layer, a pixel electrode above the support layer, and having an isolated shape in plan view, and a first intermediate layer separated from the patterning wire, and covering the pixel electrode.

### CROSS-REFERENCE TO RELATED APPLICATION

The present application claims priority to and the benefit of Korean Patent Application No. 10-2024-0199337, filed on Dec. 27, 2024, in the Korean Intellectual Property Office, the entire disclosure of which is incorporated herein by reference.

### BACKGROUND

### 1. Field

One or more embodiments of the present disclosure may relate to a display panel and an electronic apparatus including the same. For example, embodiments of the present disclosure may relate to a display panel having a reduced (e.g., simplified) manufacturing process and an electronic apparatus including the display panel.

### 2. Description of the Related Art

In some cases, a display panel may include various display elements, for example, an organic light-emitting element may be provided as a display element. Because the organic light-emitting element may include an intermediate layer including an emission layer, a display panel and an electronic apparatus including the same may display images by using light generated from the emission layer.

### SUMMARY

Display panels and electronic apparatuses including the same may require relatively substantial (e.g., significant) cost and time to pattern an emission layer during a manufacturing process.

One or more embodiments may include a display panel having a reduced (as used herein, “reduced” may mean “simplified,” as appropriate) manufacturing process and an electronic apparatus including the display panel. However, descriptions are examples illustrative of the present disclosure and are not to be construed as limiting thereof. Additional aspects will be set forth in part in the description which follows and, in part, will be apparent from the description, or may be learned by practice of the presented embodiments of the disclosure.

In one or more embodiments of a display panel, a display panel includes a substrate, a planarization layer above the substrate, a support layer above the planarization layer, and having an isolated shape in plan view, a patterning wire above the planarization layer, and contacting a side surface of the support layer, a pixel electrode above the support layer, and having an isolated shape in plan view, and a first intermediate layer separated from the patterning wire, and covering the pixel electrode.

The patterning wire may surround the support layer in plan view.

The edge of the first intermediate layer may contact an upper surface of the support layer outside the pixel electrode in plan view.

The first intermediate layer may be configured to be deformed by heat.

The display panel may further include a second intermediate layer above the first intermediate layer, the patterning wire, and the planarization layer; and a common electrode above the second intermediate layer.

The first intermediate layer may include a hole transport layer and an emission layer, and the second intermediate layer may include an electron transport layer.

The patterning wire may be electrically connected to the common electrode.

The resistance of the patterning wire may be greater than a resistance of the pixel electrode.

The support layer may include an inorganic insulating material.

In one or more embodiments of a display panel, a display panel includes a substrate, a planarization layer above the substrate, support layers spaced apart from each other above the planarization layer, and having an isolated shape in plan view, a patterning wire above the planarization layer, and contacting one or more side surfaces of the support layers, pixel electrodes respectively above the support layers, and having an isolated shape in plan view, and first intermediate layers apart from the patterning wire, and respectively above the pixel electrodes.

The patterning wire may surround one or more of the support layers in plan view.

The patterning wire may include surrounding wires respectively surrounding the support layers, and connection wires electrically connecting the surrounding wires.

The surrounding wires may be integral with the connection wires.

The edges of the first intermediate layers may respectively contact the support layers.

The first intermediate layers may be configured to be deformed by heat.

The display panel may further include a second intermediate layer above the first intermediate layers, the patterning wire, and the planarization layer, and corresponding to the pixel electrodes, and a common electrode above the second intermediate layer, and corresponding to the pixel electrodes.

One or more of the first intermediate layers may include a hole transport layer and an emission layer, and the second intermediate layer may include an electron transport layer.

The patterning wire may be electrically connected to the common electrode.

The resistance of the patterning wire may be greater than a resistance of one or more of the pixel electrodes.

In one or more embodiments of an electronic apparatus, an electronic apparatus includes a processor, and a display panel configured to be controlled by the processor, the display panel including a substrate, a planarization layer above the substrate, a support layer above the planarization layer, a patterning wire above the planarization layer and configured to contact the support layer, a pixel electrode above the support layer, and a first intermediate layer above the pixel electrode.

Aspects other than those described above will become apparent from the following detailed description, the appended claims, and the accompanying drawings.

### BRIEF DESCRIPTION OF THE DRAWINGS

The above and other aspects of the present disclosure will be more clearly understood by describing in detail embodiments thereof with the accompanying drawings, in which:

FIG. 1 is a block diagram illustrating an electronic apparatus according to embodiments of the present disclosure;

FIG. 2 is a diagram of examples of electronic apparatuses according to embodiments of the present disclosure;

FIG. 3 is a diagram illustrating examples of electronic apparatuses as wearable electronic apparatuses, according to embodiments of the present disclosure;

FIG. 4 is a diagram illustrating an electronic apparatus as a vehicle electronic apparatus, according to embodiments of the present disclosure;

FIG. 5 is a diagram of a plan view illustrating a display module according to embodiments of the present disclosure;

FIG. 6 is a diagram of a side view illustrating the display module of FIG. 5;

FIG. 7 is a diagram of a cross-sectional view illustrating a cross-section of the display panel of FIG. 5 taken along the line A-A′;

FIG. 8 is a diagram of a plan view illustrating a region of a display panel according to embodiments of the present disclosure;

FIG. 9 is a diagram of a plan view illustrating a region of a display panel according to embodiments of the present disclosure;

FIGS. 10 to 15 are diagrams of cross-sectional views for illustrating example operations of manufacturing the display panel of FIG. 7;

FIG. 16 is a diagram of a plan view illustrating a region of a display panel according to embodiments of the present disclosure;

FIG. 17 is a diagram of a cross-sectional view illustrating a region of a display panel according to embodiments of the present disclosure; and

FIG. 18 is a diagram of a cross-sectional view illustrating a region of a display panel according to embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, and/or the like) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection.

For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” and/or the like, may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” and/or the like. may also be used herein to differentiate different categories or sets of elements. For conciseness, the terms “first,” “second,” and/or the like may represent “first-category (or first-set),” “second-category (or second-set),” and/or the like, respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices, such as field programmable gate arrays (FPGAs).

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interactive individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

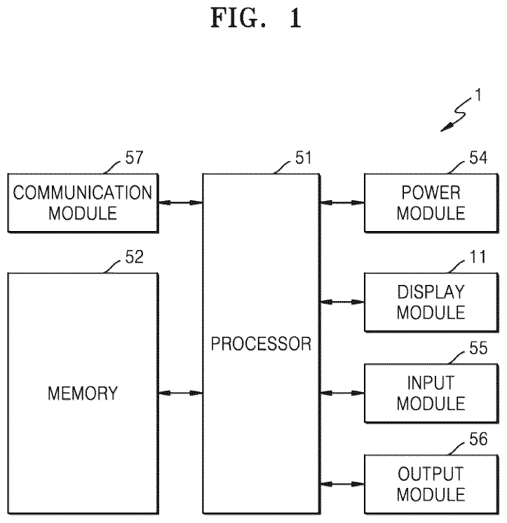

FIG. 1 is a block diagram illustrating an electronic apparatus 1 according to embodiments of the present disclosure. According to one or more embodiments, the electronic apparatus 1 may include a display apparatus and may further include one or more modules implementing functions in addition to a display module 11.

As shown in FIG. 1, according to one or more embodiments, the electronic apparatus 1 may include the display module 11, a processor 51, a memory 52, a power module 54, an input module 55, an output module 56, and a communication module 57.

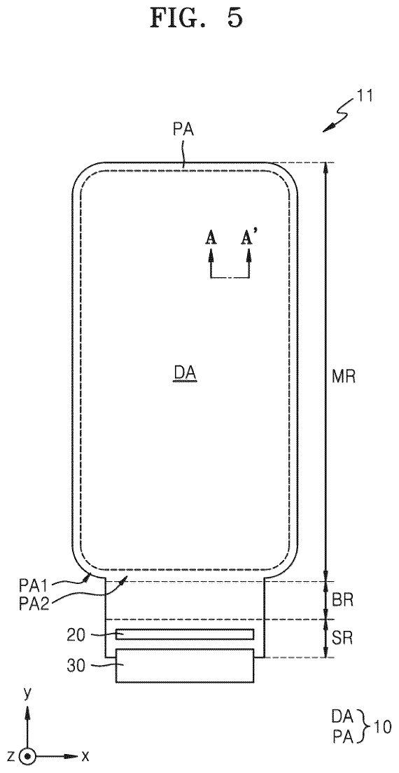

The display module 11 may include a display panel 10 (e.g., see FIG. 5) as described below. For example, the display module 11 may include the display panel 10 and a data driver 20 (e.g., see FIG. 5) arranged thereon. The display panel 10 is described in greater detail below, for example in reference to FIG. 5.

The processor 51 may control components of the electronic apparatus 1. For example, the processor 51 may output digital video data to the display module 11 such that the display module 11 may display an image, and may receive input data from the input module 55 such that a function according to the input data may be performed in the electronic apparatus 1. The processor 51 may include at least one of a central processing unit (CPU), an application processor (AP), a graphics processing unit (GPU), a communication processor (CP), and/or an image signal processor (ISP).

In one or more embodiments, the processor 51 may be divided into two or more processors from functional and/or structural aspects. For example, the processor 51 may include a main processor that is implemented as a first driving chip including a CPU, and an auxiliary processor that is implemented as a second driving chip that is a section (e.g., component) of the display module 11. The auxiliary processor (implemented as the second driving chip) may include a controller that may be configured to receive an image signal from the main processor and process the image signal according to interface function, design, and/or performance standards (e.g., specifications) of the display panel 10 included in the display module 11.

The memory 52 may include at least one of a non-volatile memory and/or a volatile memory. The memory 52 may store data utilized for the operation of the processor 51 and/or the display module 11. For example, when the processor 51 executes an application stored in the memory 52, an input control signal and/or a data signal for an image may be transmitted to the display module 11, and the display module 11 may output image information by processing the received signal.

The power module 54 may include a power supply module, such as a power adapter and/or a battery apparatus, and a power conversion module that may be configured to generate power utilized for the operation of the electronic apparatus 1, for example by converting power that is supplied by the power supply module. Power conversion performed by the power conversion module may include direct current (DC)-DC conversion, alternating current (AC)-DC conversion, and DC-AC conversion. One or more embodiments of the present disclosure are not limited thereto, and those skilled in the art will readily appreciate that modifications are possible in the embodiments without materially departing from the aspects of the present disclosure.

The input module 55 may provide input to the processor 51 and/or the display module 11. The input module 55 may include a physical button, a keyboard, and a microphone, as well as one or more sensor modules. Examples of the sensor modules may include a touch sensor, a pressure sensor, a distance sensor, a position sensor, a digitizer, a motion recognition sensor, a camera sensor, a light reception sensor, a photoelectric conversion sensor, a temperature sensor, and/or the like. Also, the sensor modules may include sensors configured to detect biological interactions (e.g., biosensors, biometric sensor, etc.), such as a blood pressure sensor, a blood glucose sensor, an electrocardiogram sensor, a heart rate sensor, and/or the like.

The output module 56 may receive information, in addition to and/or in lieu of the image received from the processor 51, and provide the information to a user. The output module 56 may include, for example, an acoustic module, a haptic module, a light-emitting module, and/or the like. Also, the output module 56 may include supplemental function modules of the electronic apparatus 1, such as a cooling module of an external cooling device (e.g., refrigerator).

In one or more embodiments, the display module 11 may also perform output functions. For example, the display panel 10 included in the display module 11 may display (output) information processed by the electronic apparatus 1. For example, the display panel 10 may display information for an execution screen related to an application running on the electronic apparatus 1, display a user interface (UI) according to the information for the execution screen, and/or display a graphic user interface (GUI). The display panel 10 may include a display layer configured to display an image, and/or a touch screen layer configured to detect a touch input from the user. In one or more embodiments, the display panel 10 may be a section of the input module 55 configured to provide an input interface between the electronic apparatus 1 and the user and may also be a section of the output module 56 configured to provide an output interface between the electronic apparatus 1 and the user.

The communication module 57 may be a module configured to transmit and/or receive information between the electronic apparatus 1 and an external apparatus and may include a receiver and/or a transmitter. The communication module 57 may include one or more wireless communication modules, such as a mobile communication module, a broadcast reception module, a wireless Internet module, a short-range communication module, a wireless-fidelity (Wi-Fi®) module, a Bluetooth® module (Wi-Fi® being a registered trademark of the non-profit Wi-Fi Alliance, and Bluetooth® being a registered trademark of Bluetooth Sig, Inc., Kirkland, WA), one or more wired communication modules, and/or the like.

The electronic apparatus 1 shown in FIG. 1 is illustrated only as an example. For example, in one or more embodiments, a display apparatus may not implement communication functions and thus may not include the communication module 57. Also, for example, in one or more embodiments the electronic apparatus 1 includes a display apparatus, and at least one of the components of the electronic apparatus 1 described above may be included in the display apparatus. In one or more embodiments, some functions that are implemented in separate modules may be included in the display apparatus, and others thereof may be included in the electronic apparatus 1. For example, the display apparatus may include the display module 11, and the processor 51, the memory 52, and the power module 54 may be components of the electronic apparatus 1. One or more embodiments of the present disclosure are not limited thereto, and those skilled in the art will readily appreciate that modifications are possible in the embodiments without materially departing from the aspects of the present disclosure. The display apparatus may include the display module 11 and the power module 54, and the power module 54 may supply power to the components of the electronic apparatus 1, such as the processor 51 and the memory 52.

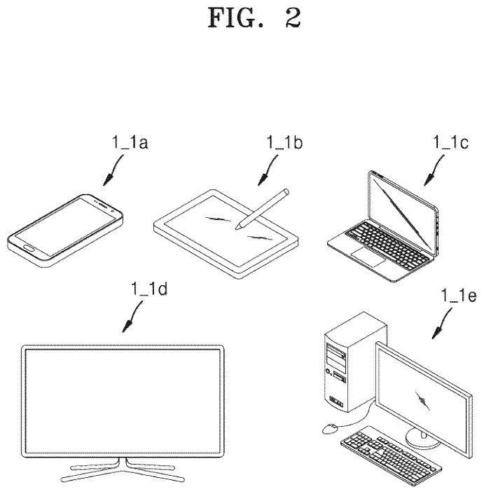

FIG. 2 is a diagram illustrating examples of the electronic apparatus 1 according to one or more embodiments. In FIG. 2, a smartphone 1_1a, a tablet personal computer (PC) 1_1b, a laptop computer 1_1c, a television (TV) 1_1d, and a desktop monitor 1_1e are shown as examples of the electronic apparatus 1.

The smartphone 1_1a may include the processor 51, the memory 52, the power module 54, the display module 11, and the input module 55, such as a touch sensor, and/or the communication module 57. The smartphone 1_1a may process information received via the communication module 57 and/or another input module and display the information via the display module 11.

In one or more embodiments, the tablet PC 1_1b, the laptop computer 1_1c, the TV 1_1d, and/or the desktop monitor 1_1e may include the display module 11 and/or the input module 55. In one or more embodiments, the tablet PC 1_1b, the laptop computer 1_1c, the TV 1_1d, and/or the desktop monitor 1_1e may also include the communication module 57.

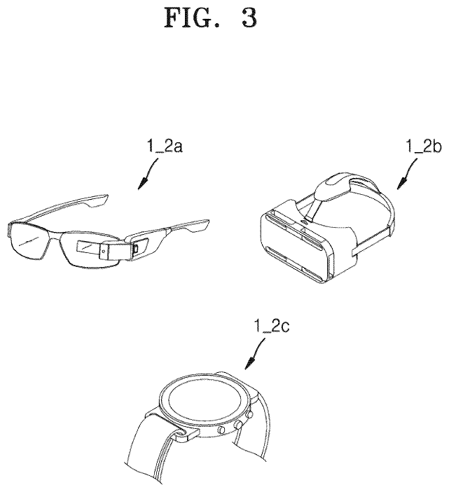

FIG. 3 is a diagram illustrating examples of the electronic apparatus 1 implemented as wearable electronic apparatuses, according to one or more embodiments. In FIG. 3, smart glasses 1_2a, a head mount display 1_2b, and a smart watch 1_2c are shown as examples of the electronic apparatus 1.

The smart glasses 1_2a and/or the head mount display 1_2b may include the display module 11 configured to display an image, and a reflector configured to reflect a display surface that displays the image and provide the image to be visible to a user (e.g., reflected towards eyes of the user). The electronic apparatus 1 may provide virtual reality technology and/or augmented reality technology to the user.

The smart watch 1_2c may include a biometric sensor as the input module 55 and may provide biometric information detected and/or identified by the biometric sensor to the user via the display module 11.

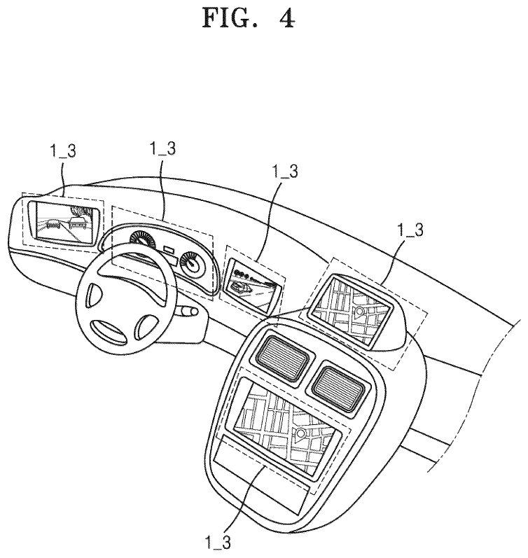

FIG. 4 is a diagram illustrating examples of the electronic apparatus 1 implemented as a vehicle electronic apparatus 1_3, according to one or more embodiments. As shown in FIG. 4, the vehicle electronic apparatus 1_3 may be implemented as a center information display (CID) included in an instrument panel and/or a center console of a vehicle, positioned over a dashboard of a vehicle, implemented as a rear mirror display of a vehicle, and/or implemented as a side mirror display of a vehicle.

The electronic apparatus 1, according to one or more embodiments of the present disclosure are not limited to the above description. For example, in one or more embodiments, the electronic apparatus 1 may include apparatuses used as displays, such as billboards, electronic boards, and/or game consoles, and/or one or more home appliances configured to display information via the display module 11, such as refrigerators, washing machines, drying machines, air conditioners, and/or robot vacuum cleaners. In one or more embodiments, the display module 11 may be configured to transmit and/or emit light, and the electronic apparatus 1 may include a smart window and/or a transparent display apparatus configured to display a background and/or a display image concurrently (e.g., together). The electronic apparatus 1 according to one or more embodiments of the present disclosure are not limited thereto. Those skilled in the art will readily appreciate that modifications are possible in the embodiments of the electronic apparatus 1 including the display panel 10 as described herein, without materially departing from the aspects of the present disclosure.

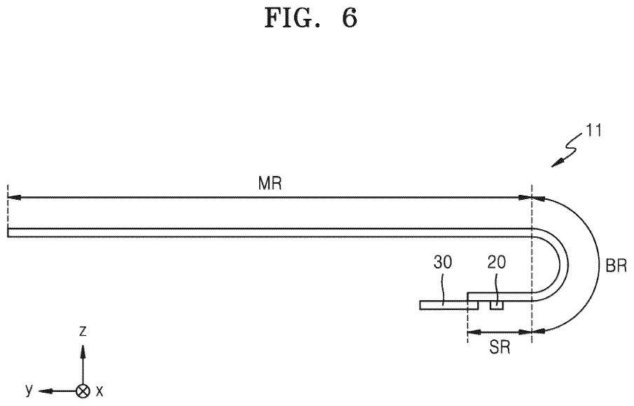

FIG. 5 is a diagram of a plan view of the display module 11 including the display panel 10, according to one or more embodiments. FIG. 6 is a diagram of a side view of the display module 11 of FIG. 5. The display module 11 included in the electronic apparatus 1 described above may include the display panel 10 as shown in FIGS. 5 and 6. The example of the display module 11 including the display panel 10 may be applicable to one or more of the example embodiments described herein and/or modifications thereof materially not departing from the aspects of the present disclosure.

In one or more embodiments, the display panel 10 may have an approximately and/or substantially rectangular (or suitable) shape. For example, in the plan view shown in FIG. 5, the display panel 10 may have a substantially rectangular shape including relatively shorter opposite sides (in an x-axis direction on a xy-plane) and relatively longer opposite sides (in a y-axis direction on a xy-plane). For example, a first side of the display panel 10 (e.g., relatively short side in the x-axis direction) and a second side of the display panel (e.g., relatively long side in the y-axis direction) may contact each other forming an edge at normal (e.g., right) angle, and/or may form an edge having a substantially round shape (e.g., having a curvature). In one or more embodiments, in the plan view, the display panel 10 may have an appropriate or suitable shape (other than the rectangular shape in FIG. 5), including a polygonal shape, an elliptical shape, an asymmetrical (e.g., irregular) shape, and/or the like.

The display panel 10 may include a display area DA and a peripheral area PA surrounding (e.g., outside) a perimeter of the display area DA. The display area DA may be a section of the display panel 10 that displays an image, and a plurality of pixels may be arranged (e.g., located) in the display area DA. The display area DA may have other appropriate and/or suitable shapes, such as a circular shape, an elliptical shape, a polygonal shape, an asymmetrical shape, and/or the like. FIG. 5 illustrates the display area DA having an approximately rectangular shape with round edges.

The peripheral area PA may be arranged around the display area DA. The peripheral area PA may include a first peripheral area PA1 surrounding at least a portion of the display area DA, and a second peripheral area PA2 arranged at a side of the display area DA and extending in a horizontal direction (x-axis direction). A width of the second peripheral area PA2 in the horizontal direction (x-axis direction) may be relatively smaller than a width of the display area DA. In one or more embodiments, at least a portion of the second peripheral area PA2 may be flexible and/or capable of bending.

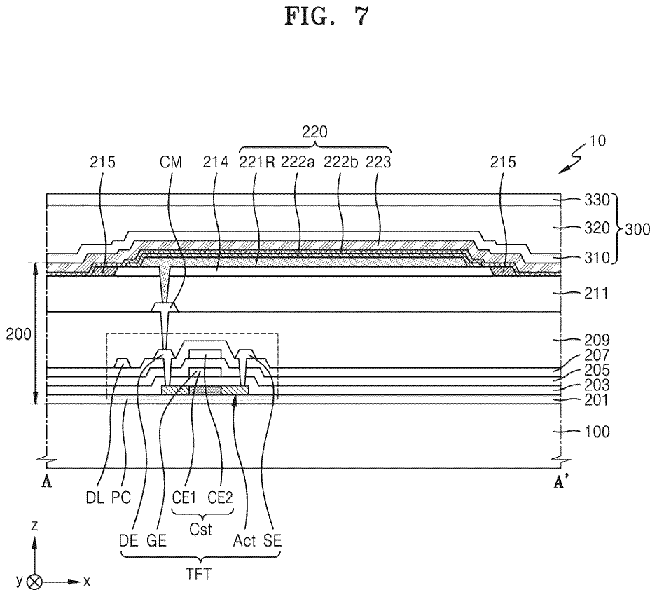

A lateral (e.g., side) plane of the display panel 10 shown in FIG. 5 may be substantially similar to a shape of a substrate 100 (see FIG. 7) included in the display panel 10. In one or more embodiments, the display panel 10 may include the display area DA and the peripheral area PA around the display area DA. The substrate 100 may include the display area DA and the peripheral area PA. Hereinafter, for purposes of description, the substrate 100 may be described as including the display area DA and the peripheral area PA.

The display panel 10 may include a main region MR, a bending region BR (e.g., arranged at an edge of the main region MR), and a subregion SR (e.g., separated from the main region MR with the bending region BR therebetween). The main region MR may be arranged on one side of the bending region BR (in the y-axis direction), and the subregion SR may be arranged on the other side (e.g., opposite side) of the bending region BR (in the y-axis direction). As shown in FIG. 6, the display panel 10 may have curvature (e.g., bent) in the bending region BR, and in a vertical direction (z-axis direction) at least a portion of the subregion SR may overlap (e.g., curved underneath) the main region MR.

FIG. 6 illustrates the display panel 10 that may be flexible and/or have a curvature. One or more embodiments of the present disclosure are not limited thereto, and those skilled in the art will readily appreciate that modifications are possible in the embodiments without materially departing from the aspects of the present disclosure. For example, the display panel 10 may be implemented as a foldable display panel, such that a section of the display panel may fold at a corner and/or a lateral edge (e.g., along a line axis). The display panel 10 may be folded in the bending region BR with respect to an axis (for bending) that is parallel across the display area DA (in the x-axis direction). In one or more embodiments, the display panel 10 may be rigid (e.g., inflexible, not bending, etc.) as suitable and/or appropriate. The subregion SR may include a non-display area.

As described above, the display panel 10 may be implemented as a rigid display panel that has resistance to bending and may be substantially inflexible (e.g., unbendable), or a flexible display panel that has flexibility and thus is substantially bendable, foldable, rollable, and/or the like. For example, the display panel 10 may include a foldable display panel that may be folded and/or unfolded, a curved display panel having a curved (e.g., including radius of curvature) display surface, a bendable display panel in which areas other than and/or in addition to a display surface may be bent, a rollable display panel that may be capable of being arranged into a rounded shape (e.g., rolled) and/or unrolled, or an extendable (e.g., stretchable) display panel that may be capable of being made longer and/or wider, and/or the like.

The display module 11 including the display panel 10 may include the data driver 20 arranged in the subregion SR of the display panel 10. The data driver 20 may be arranged on (e.g., connected to) the display panel 10 and may be implemented as an integrated circuit (IC). For example, the data driver 20 may include a data driving IC configured to generate a data signal. As described above, the data driver 20 may include a second (e.g., auxiliary) processor implemented as a second driving chip, and may be a portion (e.g., component) of the processor 51.

A display circuit board 30 may be connected (e.g., attached) to an end surface of the subregion SR of the display panel 10. For example, the display module 11 may include the display circuit board 30. The display circuit board 30 may be connected to form an electrical connection to the data driver 20 via a conductive pad of the subregion SR of the display panel 10.

FIG. 7 is diagram of a cross-sectional view of a cross-section of the display panel 10 of FIG. 5 taken along the line A-A′ (in the x-axis direction). As shown in FIG. 7, the display panel 10 may include the substrate 100. One or more components of the display panel 10 may be arranged on the substrate 100. For example, a display layer 200 and a thin-film encapsulation layer 300 may be arranged above (e.g., on top of) the substrate 100.

The substrate 100 may include materials, such as glass, ceramic, metal, polymer resin, and/or the like. The substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. The substrate 100 may be configured as a multilayer (e.g., multiple layers) structure including two layers including the polymer resin and an inorganic layer therebetween. In one or more embodiments, the substrate 100 may be configured as a structure having a first layer including the polymer resin and a second layer, an inorganic layer, are arranged such that the first layer and the second layer are alternately positioned on top of each other (e.g., stacked) for multiple layers. The inorganic layer may include materials, for example, silicon oxide, silicon nitride, silicon oxynitride, and/or the like, and may have a structure with one or more layers, for example a single-layer structure or a multilayer structure. The inorganic layer may be implemented as a layer forming a barrier that prevents or reduces external and/or foreign materials from entering into (as used herein, “entering into” may mean “penetration,” as appropriate) the display panel 10.

The display layer 200 may include a plurality of pixels. The display layer 200 may include a display element 220 arranged in one or more of the pixels (as used herein, “one or more of” may mean “each of,” as appropriate), a pixel circuit arranged in one or more of the pixels, and insulating layers. The pixel circuit may include one or more transistors, shown as thin film transistor TFT and one or more capacitors, shown as storage capacitor Cst. The display element 220 may include, for example, an organic light-emitting diode (OLED).

The thin-film encapsulation layer 300 may be arranged above (e.g., as used herein, “above” may mean “covering,” as appropriate) the display layer 200. The thin-film encapsulation layer 300 may include at least one inorganic encapsulation layer and at least one organic encapsulation layer. The thin-film encapsulation layer 300 may prevent or reduce external and/or foreign materials (e.g., impurities, contaminants, pollutants, etc.) such as moisture, from the outside (e.g., external to the display panel 10) from entering into a display element 220.

Hereinafter, the display layer 200 and the thin-film encapsulation layer 300 are described in detail.

A buffer layer 201 may be arranged above (e.g., over) the substrate 100 to prevent or reduce external and/or foreign materials from entering into a semiconductor layer Act of the thin-film transistor TFT. The buffer layer 201 may include an inorganic insulating material, such as silicon nitride, silicon oxynitride, silicon oxide, and/or the like, and may be configured to have a single-layer structure or a multilayer structure.

A pixel circuit PC may be arranged above (e.g., over) the buffer layer 201. The pixel circuit PC may include a thin-film transistor TFT and a storage capacitor Cst. The thin-film transistor TFT may include a semiconductor layer Act, a gate electrode GE, a source electrode SE, and/or a drain electrode DE. The thin-film transistor TFT shown in FIG. 7 may be implemented as a driving transistor configured to control one or more aspects of the pixel circuit PC and/or the display panel 10. In one or more embodiments, an emission control transistor may be arranged between the driving transistor and the OLED, and the thin-film transistor TFT, which is a driving transistor, may not be connected to a pixel electrode of the OLED, for example, a red pixel electrode 221R, via a contact metal layer CM. The thin-film transistor TFT may be electrically connected to the emission control transistor, and the emission control transistor may be electrically connected to the pixel electrode of the OLED. In one or more embodiments, the thin-film transistor TFT shown in FIG. 7 may be implemented as the emission control transistor. Hereinafter, for purposes of description, a structure in which the thin-film transistor TFT of FIG. 7 is connected to the pixel electrode of the OLED, for example, a red pixel electrode 221R, via the contact metal layer CM is described.

In one or more embodiments, a data line DL of the pixel circuit PC may be electrically connected to a switching transistor included in the pixel circuit PC.

The semiconductor layer Act may include polysilicon. In one or more embodiments, the semiconductor layer Act may include amorphous silicon, an oxide semiconductor, an organic semiconductor, and/or the like. The gate electrode GE may include a conductive and/or substantively low resistance metal material. For example, the gate electrode GE may include a conductive material including molybdenum (Mo), aluminum (Al), copper (Cu), titanium (Ti), and/or the like, and may be configured to have a single-layer structure or a multilayer structure. For example, the gate electrode GE may have a three-layer structure including a Mo layer, an Al layer, and a Mo layer (Mo/Al/Mo).

A gate-insulating layer 203 may be arranged between the semiconductor layer Act and the gate electrode GE. In one or more embodiments, the gate-insulating layer 203 may include an inorganic insulating material, such as silicon oxide, silicon nitride, silicon oxynitride, aluminum oxide, titanium oxide, tantalum oxide, hafnium oxide, and/or the like. The gate-insulating layer 203 may be configured to have a single-layer structure or a multilayer structure.

The source electrode SE and the drain electrode DE may be arranged on a substantially similar (as used herein, “substantially similar” may mean “same,” as appropriate) layer as the data line DL, and may include the substantially similar material as the data line DL. One or more of the source electrode SE, the drain electrode DE, and the data line DL may include a material having relatively high conductivity. One or more of the source electrode SE and the drain electrode DE may include a conductive material, such as Mo, Al, Cu, or Ti, and may be configured to have a multilayer structure or a single-layer structure. For example, one or more of the source electrode SE, the drain electrode DE, and the data line DL may be configured as a multilayer structure including a Ti layer, an Al layer, and a Ti layer (Ti/Al/Ti).

FIG. 7 illustrates a configuration of the thin-film transistor TFT that may include the source electrode SE and the drain electrode DE. One or more embodiments of the present disclosure are not limited thereto, and those skilled in the art will readily appreciate that modifications are possible in the embodiments without materially departing from the aspects of the present disclosure. For example, a drain region of the semiconductor layer Act of the thin-film transistor TFT may be integrally formed (as used herein, “formed” may mean “provided,” as appropriate) as a single body with a source region of a semiconductor layer of another thin-film transistor. In this example, the thin-film transistor TFT may not include the drain electrode DE, and the other thin-film transistor may not include a source electrode. Thus, in one or more embodiments, a drain region of the thin-film transistor TFT may be connected to a source region of the other thin-film transistor. For example, when a drain region of the driving transistor is connected to a source region of the emission control transistor, the driving transistor may not include a drain electrode, and the emission control transistor may not include a source electrode. A drain region of a semiconductor layer of the driving transistor and a source region of the emission control transistor may be integrally formed as a single body. In one or more embodiments, when a source region of the driving transistor is connected to a drain region of an operation control transistor, the driving transistor may not include a source electrode, and the operation control transistor may not include a drain electrode. A source region of the semiconductor layer of the driving transistor and a drain region of the operation control transistor may be integrally formed as a single body. Thus, in one or more embodiments, the driving transistor may not include the source electrode and/or the drain electrode.

The storage capacitor Cst may include a first (e.g., lower) electrode CE1 that may be arranged below (e.g., overlapping) a second (e.g., upper) electrode CE2, with a first interlayer insulating layer 205 therebetween. The storage capacitor Cst may be arranged proximately to and/or substantially within (e.g., overlap) the thin-film transistor TFT. FIG. 7 illustrates that the gate electrode GE of the thin-film transistor TFT may be the lower electrode CE1 of the storage capacitor Cst. One or more embodiments of the present disclosure are not limited thereto, and those skilled in the art will readily appreciate that modifications are possible in the embodiments without materially departing from the aspects of the present disclosure. In one or more embodiments, the storage capacitor Cst may be arranged to not overlap the thin-film transistor TFT. A second interlayer insulating layer 207 may be arranged above the storage capacitor Cst. The second (e.g., upper) electrode CE2 of the storage capacitor Cst may include a conductive material including Mo, Al, Cu, Ti, and/or the like, and may be configured to have a multilayer structure or a single-layer structure.

One or more of the first interlayer insulating layer 205 and the second interlayer insulating layer 207 may include an inorganic insulating material, such as silicon oxide, silicon nitride, silicon oxynitride, aluminum oxide, titanium oxide, tantalum oxide, hafnium oxide, and/or the like. One or more of the first interlayer insulating layer 205 and the second interlayer insulating layer 207 may be configured to have a single-layer structure or a multilayer structure.

The first organic insulating layer 209 may be arranged on top of the pixel circuit PC including the thin-film transistor TFT and the storage capacitor Cst.

The pixel circuit PC may be electrically connected to a pixel electrode, for example, the red pixel electrode 221R. For example, as shown in FIG. 7, the contact metal layer CM may be arranged between the thin-film transistor TFT and the red pixel electrode 221R. The contact metal layer CM may be connected to the thin-film transistor TFT via a contact hole formed (or defined) in the first organic insulating layer 209, and the red pixel electrode 221R may be connected to the contact metal layer CM via a contact hole, which is formed (or defined) in a second organic insulating layer 211 (arranged on the first organic insulating layer 209) on top of the contact metal layer CM. The contact metal layer CM may include a conductive material including Mo, Al, Cu, Ti, and/or the like, and may be configured to have a single-layer structure or a multilayer structure. For example, the contact metal layer CM may have a multilayer structure including a Ti layer, an Al layer, and a Ti layer (Ti/Al/Ti).

One or more of the first organic insulating layer 209 and the second organic insulating layer 211 may include an organic insulating material, such as acryl, polystyrene (PS), polymethylmethacrylate (PMMA), benzocyclobutene (BCB), polyimide, hexamethyldisiloxane (HMDSO), and/or the like. For example, the first organic insulating layer 209 and/or the second organic insulating layer 211 may include polyimide. The first organic insulating layer 209 and/or the second organic insulating layer 211 may have an approximately level (e.g., flat) upper surface. For example, the first organic insulating layer 209 and/or the second organic insulating layer 211 may be configured as a planarization layer providing a level surface.

A support layer 214 may be arranged over the second organic insulating layer 211. For example, in a plan view and in a direction (z-axis direction) that is normal (e.g., perpendicular) to the substrate 100, the support layer 214 may have a distinct and/or separate shape. The support layer 214 may include an inorganic insulating material, such as silicon oxide, silicon nitride, silicon oxynitride, aluminum oxide, titanium oxide, tantalum oxide, hafnium oxide, and/or the like. The support layer 214 including the inorganic insulating material may be formed utilizing chemical vapor deposition (CVD).

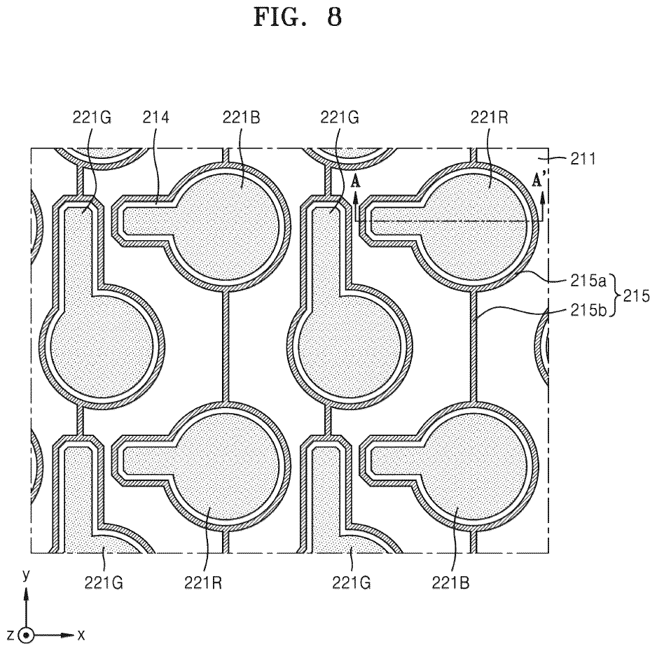

FIG. 7 is a diagram illustrating a cross-sectional view of a pixel (subpixel) including a support layer 214. One or more embodiments of the present disclosure are not limited thereto, and those skilled in the art will readily appreciate that modifications are possible in the embodiments without materially departing from the aspects of the present disclosure. For example, as shown in FIG. 8, which is a diagram of a plan view of a region of the display panel 10 according to one or more embodiments, the display panel 10 may include a plurality of support layers 214 on the second organic insulating layer 211. In a plan view (i.e., when viewed in the z-axis direction) that may be normal (e.g., perpendicular) to the substrate 100, one or more of the support layers 214 may have a separate and/or distinct shape and the support layers may be separate from each other. For example, FIG. 7 is a diagram of a cross-sectional view of a cross-section of the display panel 10 along a horizontal line A-A′ (in an x-axis direction) of FIG. 8. FIG. 8 illustrates examples of one or more of the components that may be included in the display panel 10. In one or more embodiments, as illustrated in FIG. 8, the display panel 10 may include a second organic insulating layer 211, the support layers 214, a patterning wire 215, the red pixel electrode 221R, a green pixel electrode 221G, and a blue pixel electrode 221B.

For example, as shown in FIG. 8, blue pixel electrodes 221B and red pixel electrodes 221R may be alternately arranged in a first row along a horizontal direction (x-axis direction), and in a second row (e.g., below the first row) in the horizontal direction (x-axis direction), green pixel electrodes 221G may be arranged. In one or more embodiments, in one column, the blue pixel electrodes 221B and the red pixel electrodes 221R may be alternately arranged in a vertical direction (y-axis direction), and in a second column in a vertical direction (y-axis direction), the green pixel electrodes 221G may be arranged in the vertical direction (y-axis direction). One or more embodiments of the present disclosure are not limited thereto, and those skilled in the art will readily appreciate that modifications to pixel electrodes, as disclosed herein, are possible in the embodiments without materially departing from the aspects of the present disclosure.

The patterning wire 215 may be arranged around the support layer 214. For example, the patterning wire 215 may be arranged throughout the second organic insulating layer 211 to contact a surface of the support layer 214 (in particular, contact a side surface of the support layer 214). The patterning wire 215 may be around (or completely surround) the support layer 214. Because the display panel 10 includes the plurality of support layers 214, the patterning wire 215 may be in contact with a surface of one or more of the plurality of support layers 214. In one or more embodiments, the patterning wire 215 may be around (or completely surround) one or more of the plurality of support layers 214.

As shown in FIG. 8, the patterning wire 215 may include surrounding wires 215a and connection wires 215b. Each of the surrounding wires 215a may be positioned around (or completely surround) a corresponding one of the plurality of support layers 214. The connection wires 215b may electrically connect the surrounding wires 215a to each other. The surrounding wires 215a and connection wires 215b may be integrally formed as a single body.

The patterning wire 215 may include Mo, Ti, or one or more compounds thereof. In one or more embodiments, the patterning wire 215 may include other conductive materials. For example, a material having a relatively higher resistance and thus generating heat when a current flows may be used as a material for forming the patterning wire 215. For example, the resistance of the patterning wire 215 may be higher than the resistance of the red pixel electrode 221R. The patterning wire 215 may be formed by using sputtering and/or other suitable processes, in one or more examples.

The red pixel electrode 221R may be arranged over the support layer 214. For example, as shown in FIG. 8, the green pixel electrode 221G and/or the blue pixel electrode 221B may be located in a pixel (subpixel) separate from (other than) a red pixel (subpixel). One or more of the red pixel electrode 221R, the green pixel electrode 221G, and/or the blue pixel electrode 221B may be arranged over a corresponding one of the plurality of support layers 214. In a direction (z-axis direction) normal to the substrate 100, one or more of the red pixel electrode 221R, the green pixel electrode 221G, and/or the blue pixel electrode 221B may have a separate and/or distinct shape. Hereinafter, for purposes of description, a configuration for the red pixel electrode 221R is described, but a substantially similar configuration may also apply to the green pixel electrode 221G and the blue pixel electrode 221B, in one or more embodiments.

As shown in FIGS. 7 and 8, the area of the red pixel electrode 221R may be relatively smaller than the area of a corresponding support layer 214, and thus, the red pixel electrode 221R may be separated from the patterning wire 215.

The red pixel electrode 221R may be a reflective electrode. For example, the red pixel electrode 221R may include a reflective layer including silver (Ag), magnesium (Mg), Al, platinum (Pt), palladium (Pd), gold (Au), nickel (Ni), neodymium (Nd), iridium (Ir), chromium (Cr), or one or more compounds thereof, and a transparent (or translucent) electrode layer on the reflective layer. The transparent electrode layer may include at least one material, including but not limited to indium tin oxide (ITO), indium zinc oxide (IZO), zinc oxide (ZnOₓ: ZnO or ZnO₂), indium oxide (In₂O₃), indium gallium oxide (IGO), aluminum zinc oxide (AZO), and/or the like. For example, the red pixel electrode 221R may be configured to have a three-layer structure including ITO/Ag/ITO. One or more of the layers included in the red pixel electrode 221R, for example, the ITO layers and the Ag layer, may be formed by using sputtering and/or other suitable process.

The red pixel electrode 221R may be connected to the contact metal layer CM below the second organic insulating layer 211 via a contact hole formed (or defined) in the second organic insulating layer 211 and the support layer 214. The red pixel electrode 221R may be electrically connected to the thin-film transistor TFT.

A first intermediate layer 222a may be arranged over the red pixel electrode 221R. The first intermediate layer 222a may be arranged above the red pixel electrode 221R such that an edge of the first intermediate layer 222a may be in contact with an upper surface of an outer portion of the support layer 214 around (e.g., outside) the red pixel electrode 221R (e.g., in plan view). For example, the first intermediate layer 222a may be separate from the patterning wire 215. In one or more embodiments, an edge of one or more of first intermediate layers 222a on another pixel electrode may be in contact with an upper surface of a corresponding one of the plurality of the support layers 214.

The first intermediate layer 222a may include an emission layer, and may include one or more other functional layers. For example, when the first intermediate layer 222a includes a polymer material, the first intermediate layer 222a may include a hole transport layer (HTL) and the emission layer. When the first intermediate layer 222a includes a material having a relatively low molecular weight, the first intermediate layer 222a may include a hole injection layer (HIL), the HTL, and the emission layer. In one or more embodiments, the first intermediate layer 222a arranged on the red pixel electrode 221R may include a red emission layer, the first intermediate layer 222a arranged on the green pixel electrode 221G may include a green emission layer, and the first intermediate layer 222a arranged on the blue pixel electrode 221B may include a blue emission layer. One or more of the layers included in the first intermediate layer 222a may be formed using deposition and/or other appropriate process.

A second intermediate layer 222b may be arranged over the first intermediate layers 222a, which are apart from each other, the patterning wire 215, and the second organic insulating layer 211. For example, the second intermediate layer 222b may be integrally formed as a single body to correspond to the entire horizontal surface (i.e., the entire surface in the x-axis and/or y-axis directions) of the substrate 100. A common electrode 223 may be integrally formed as a single body to correspond to the entire horizontal surface (i.e., the entire surface in the x-axis and/or y-axis directions) of the substrate 100 and may be arranged over the second intermediate layer 222b.

The second intermediate layer 222b may include an electron transport layer (ETL) and/or an electron injection layer (EIL). The common electrode 223 may include a transmissive electrode and/or a semi-transmissive electrode. For example, the common electrode 223 may include a metal thin film having a relatively low (or small) work function, including lithium (Li), calcium (Ca), Al, Ag, Mg, one or more compounds thereof (e.g., lithium fluoride (LiF)), and/or the like. In one or more embodiments, the common electrode 223 may further include a transparent conductive oxide (TCO) layer, such as ITO, IZO, ZnO, ZnO₂, In₂O₃, and/or the like (arranged over the metal thin film).

In one or more embodiments, in reference to the red pixel (subpixel), a stacked multilayered structure including the red pixel electrode 221R, the first intermediate layer 222a, the second intermediate layer 222b, and the common electrode 223 may correspond to an OLED, which may be a display element 220. In one or more embodiments, in reference to a green pixel (subpixel), a stacked multilayered structure including the green pixel electrode 221G, the first intermediate layer 222a, the second intermediate layer 222b, and the common electrode 223 may correspond to an OLED, which may be a display element 220. In one or more embodiments, in reference to the blue pixel (subpixel), a stacked multilayered structure including the blue pixel electrode 221B, the first intermediate layer 222a, the second intermediate layer 222b, and the common electrode 223 may correspond to an OLED, which may be a display element 220.

In one or more embodiments, a capping layer may be arranged over the common electrode 223. The capping layer may include, for example, LiF. In one or more embodiments, the capping layer may not be provided.

The thin-film encapsulation layer 300 may be arranged above the display element 220, such as an OLED. When a capping layer is included in the structure, the thin-film encapsulation layer 300 may be arranged over the capping layer. The thin-film encapsulation layer 300 may include at least one organic encapsulation layer and at least one inorganic encapsulation layer. FIG. 7 illustrates one or more embodiments of the thin-film encapsulation layer 300 that may include a first inorganic encapsulation layer 310, a second inorganic encapsulation layer 330, and an organic encapsulation layer 320 therebetween. In one or more embodiments of the present disclosure, a number of organic encapsulation layers, a number of inorganic encapsulation layers, and a stacking order of the layers may be modified as suitable and/or appropriate.

One or more of the first inorganic encapsulation layer 310 and/or the second inorganic encapsulation layer 330 may include at least one inorganic material, including aluminum oxide, titanium oxide, tantalum oxide, hafnium oxide, zinc oxide, silicon oxide, silicon nitride, silicon oxynitride, and/or the like. One or more of the first inorganic encapsulation layer 310 and/or the second inorganic encapsulation layer 330 may be configured to have a single-layer structure or a multilayer structure. The organic encapsulation layer 320 may include a polymer-based material. The polymer-based material may include an acrylic resin, such as PMMA or polyacrylate, an epoxy resin, polyimide, polyethylene, and/or the like. For example, the organic encapsulation layer 320 may include acrylate.

The first inorganic encapsulation layer 310 and/or the second inorganic encapsulation layer 330 may respectively include one or more different materials. For example, the first inorganic encapsulation layer 310 may include silicon oxynitride, and the second inorganic encapsulation layer 330 may include silicon nitride.

The first inorganic encapsulation layer 310 may be configured to have a curved portion, for example substantially similar to the shape of the common electrode 223. The organic encapsulation layer 320 may have a substantially level (e.g., flat) upper surface, and accordingly, the second inorganic encapsulation layer 330 may also have a substantially similar flat upper surface.

As described above with reference to FIG. 8, the patterning wire 215 may include the surrounding wires 215a and the connection wires 215b. One or more of the surrounding wires 215a may be around (or completely surround) a corresponding one of the plurality of support layers 214. The connection wires 215b may electrically connect the surrounding wires 215a to each other. FIG. 8 illustrates that the connection wires 215b may have a substantially linear shape extending approximately in the vertical direction (y-axis direction) and normal to the horizonal direction (x-axis direction) such that surrounding wires 215a in the same column are electrically connected to each other. One or more embodiments of the present disclosure are not limited thereto, and those skilled in the art will readily appreciate that modifications are possible in the embodiments without materially departing from the aspects of the present disclosure.

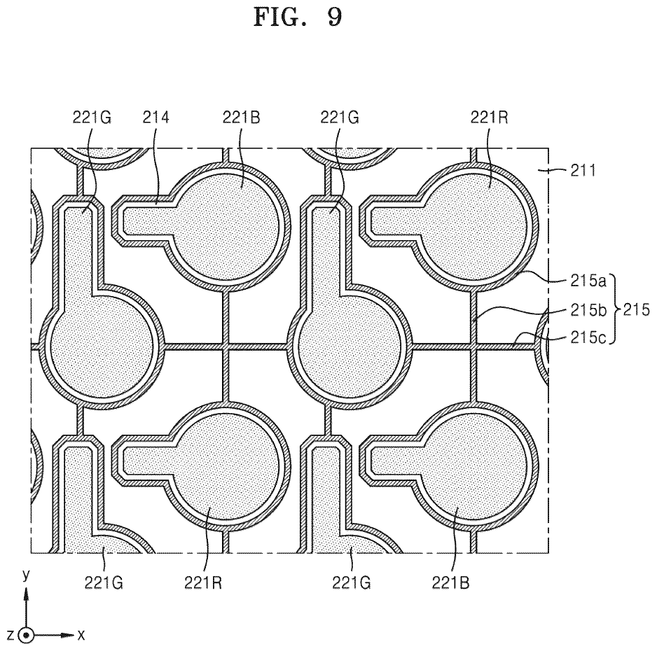

FIG. 9 is a diagram illustrating a plan view of a region of the display panel 10 according to one or more embodiments. For example, as shown in FIG. 9, the patterning wire 215 may include the connection wires 215b having a substantially linear shape extending approximately in the vertical direction (y-axis direction), and connection wires 215c having a substantially linear shape extending approximately in the horizontal direction (x-axis direction). Accordingly, the patterning wire 215 may have a mesh (e.g., crossed perpendicular lines) structure in the display area DA. The surrounding wires 215a, the connection wires 215b, and the connection wires 215c may be integrally formed as a single structural component (e.g., body), in one or more embodiments.

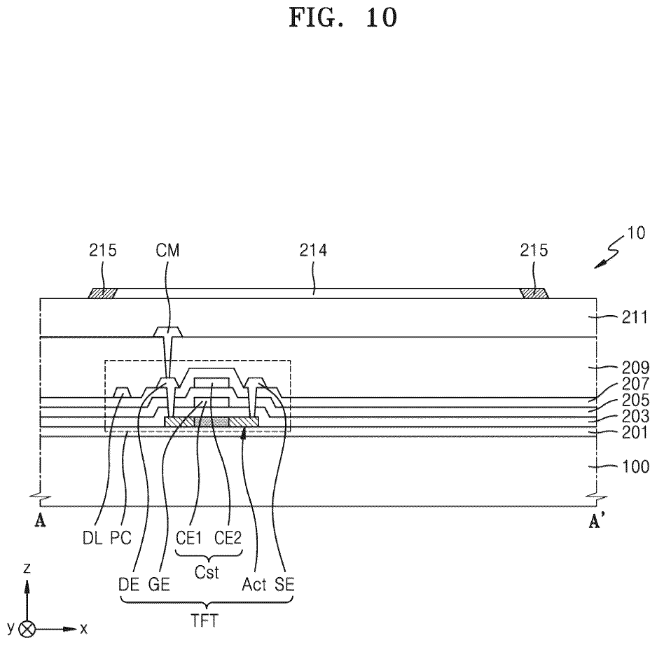

Examples of operations in a method of manufacturing the display panel 10 of FIG. 7 are described with reference to FIGS. 10 to 15.

A first operation in a method of manufacturing the display panel 10 is shown in FIG. 10. In FIG. 10, the plurality of support layers 214 may be formed on the second organic insulating layer 211. As described above, for example with reference to FIGS. 8 and 9, one or more of the plurality of support layers 214 may have a distinct and/or separate shape in the plan view and the plurality of support layers may be separated from each other. The plurality of support layers 214 may be formed by arranging an insulating layer on the entire horizontal surface (i.e., the entire surface in the x-axis and y-axis directions) of the substrate 100 using CVD, and then patterning the insulating layer using a photoresist. The insulating layer may include an inorganic insulating material. Then, a conductive layer may be formed on the surface of the substrate 100, for example using sputtering, and arranged above the second organic insulating layer 211 and the plurality of support layers 214. Then, the conductive layer may be patterned by using a photoresist, thereby forming the patterning wire 215 as shown in FIG. 10. The shape of the patterning wire 215 is as described above with reference to FIGS. 7 to 9.

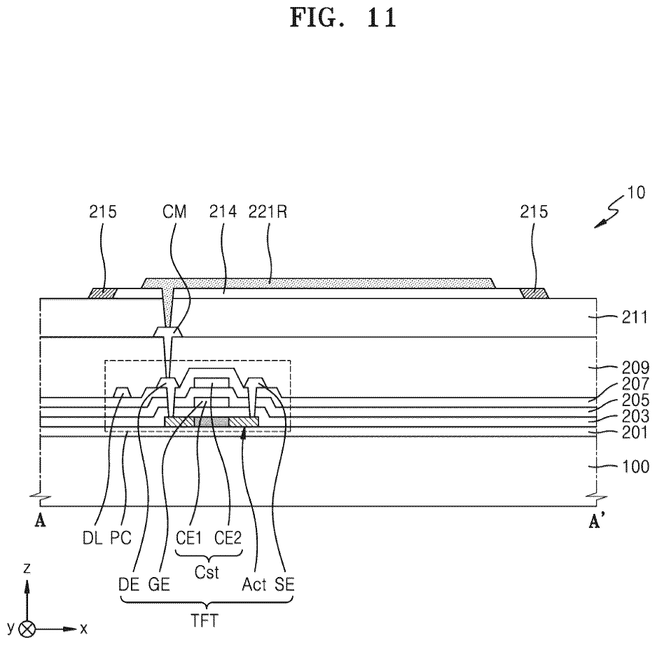

Thereafter, as shown in FIG. 11, contact holes may be formed in the plurality of support layers 214 through the second organic insulating layer 211, such that a portion of one or more of the contact metal layers CM may be exposed. Next, a material layer for forming a pixel electrode may be arranged, for example using sputtering, to fill the contact holes and cover the second organic insulating layer 211, the support layers 214, and the patterning wire 215. The material layer for forming the pixel electrode may be arranged and/or patterned, for example using a photoresist, thereby forming the red pixel electrodes 221R as shown in FIG. 11. In one or more embodiments, the green pixel electrodes 221G and the blue pixel electrodes 221B may also be formed concurrently (e.g., simultaneously).

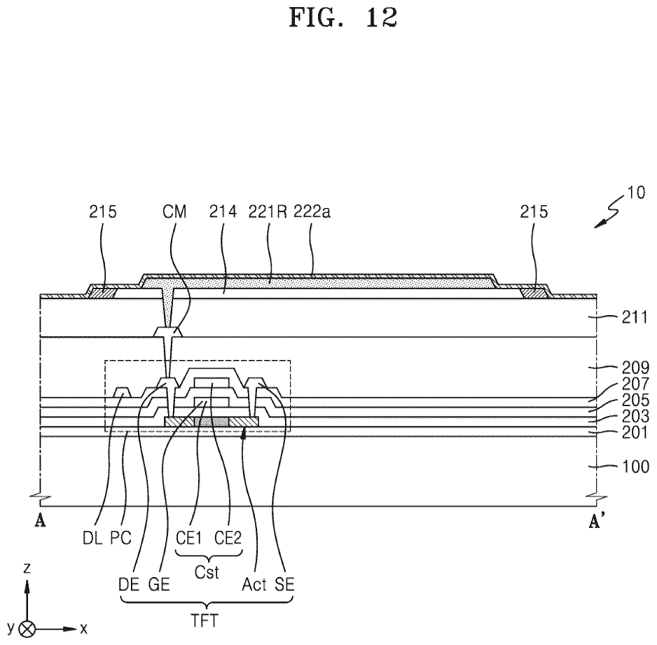

Next, as shown in FIG. 12, the first intermediate layer 222a including the red emission layer may be formed, for example using deposition, to correspond to the entire horizontal surface (i.e., the entire surface in the x-axis and/or y-axis directions) of the substrate 100. As shown in FIG. 12, the first intermediate layer 222a may be arranged above the second organic insulating layer 211, the support layers 214, the patterning wire 215, and the red pixel electrodes 221R. In one or more embodiments, the first intermediate layer 222a including the red emission layer, may also be arranged over the green pixel electrodes 221G and the blue pixel electrodes 221B.

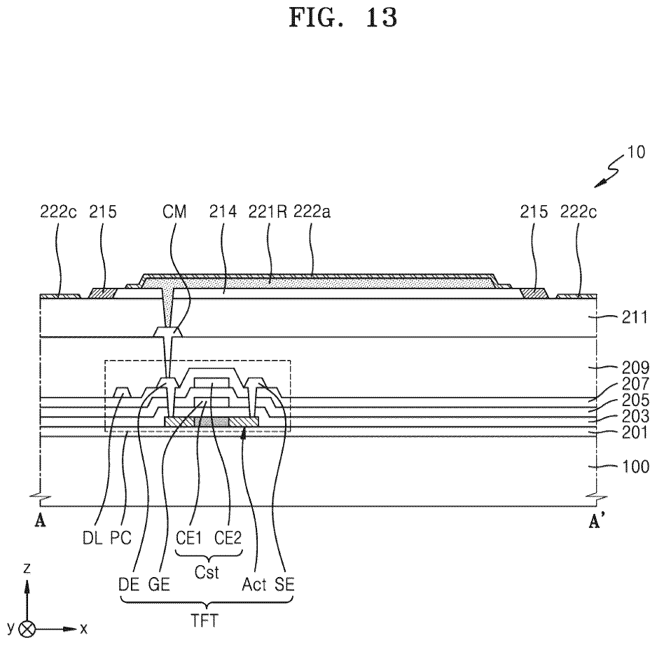

In an operation, a current may flow through the patterning wire 215 to generate (or provide) heat in the patterning wire 215 such that, as shown in FIG. 13, the first intermediate layer 222a including the red emission layer may be disconnected at the position of the patterning wire 215. For example, a portion of the first intermediate layer 222a including the red emission layer, which may be adjacent to the patterning wire 215, may be removed (e.g., disconnected) by the heat generated in the patterning wire 215. Accordingly, an edge of the first intermediate layer 222a arranged to correspond to the red pixel electrode 221R may be in contact with an upper surface of an outer portion of the support layer 214 around (e.g., outside) the red pixel electrode 221R and may be separate from the patterning wire 215. In one or more embodiments, a first intermediate layer residual portion 222c may be separate from the patterning wire 215 and may be arranged on the second organic insulating layer 211. As described above, because the first intermediate layer 222a including the red emission layer may be impacted by the heat generated in the patterning wire 215, the first intermediate layer 222a may have, at the edge thereof, a portion deformed (e.g., degenerated) by the heat.

In one or more embodiments, as described above, the support layer 214 may include an inorganic insulating material. Accordingly, when heat is generated in the patterning wire 215, the support layer 214 may not be deformed. In one or more embodiments when the support layer 214 may be deformed, the degree of deformation (or degeneration) may be minimized and/or reduced.

As described above, to generate a current to flow through the patterning wire 215 during the manufacturing process, the patterning wire 215 may extend outside of the display area DA and extend to the peripheral area PA. In one or more embodiments, during the manufacturing process, the first intermediate layer 222a may be arranged by a current to flow through the patterning wire 215 in the peripheral area PA.

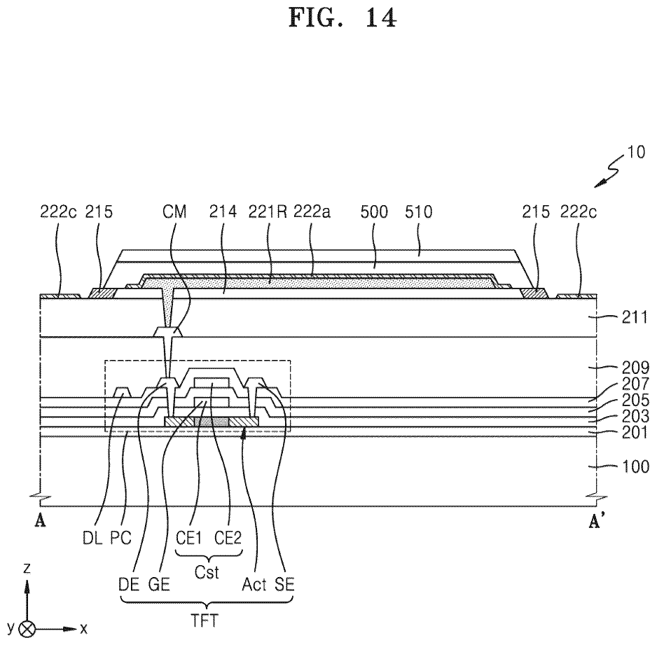

Then, an insulating layer may be formed to correspond to the entire l horizontal surface (i.e., the entire surface in the x-axis and/or y-axis directions) of the substrate 100 and the insulating layer may be arranged using a photoresist, for example. As shown in FIG. 14, sacrificial layers 500 may be arranged above the first intermediate layers 222a over the support layers 214. In one or more embodiments, the first intermediate layer residual portion 222c may be exposed (e.g., without being covered with the sacrificial layers 500). The sacrificial layers 500 may have a shape substantially similar to the shape of the support layers 214 in the plan view. For example, for the first intermediate layers 222a to be covered with the sacrificial layers 500, the sacrificial layers 500 may cover at least a portion of an upper surface of the patterning wire 215. FIG. 14 illustrates that an edge of one or more of the sacrificial layers 500 may be arranged over the upper surface of the patterning wire 215. One or more of the sacrificial layers 500 may include an inorganic insulating material, such as silicon oxide, silicon nitride, silicon oxynitride, aluminum oxide, titanium oxide, tantalum oxide, hafnium oxide, and/or the like.

Thereafter, as shown in FIG. 14, photoresists 510 may be arranged on top of the sacrificial layers 500. One or more portions of the photoresists 510 may be removed, for example using dry etching, and the first intermediate layer residual portion 222c exposed (e.g., without being covered with the sacrificial layers 500) may be removed concurrently (e.g., simultaneously). One or more of the first intermediate layers 222a, including the red emission layer, may be protected and/or covered by the sacrificial layers 500 while maintaining the arranged shapes (or patterns).

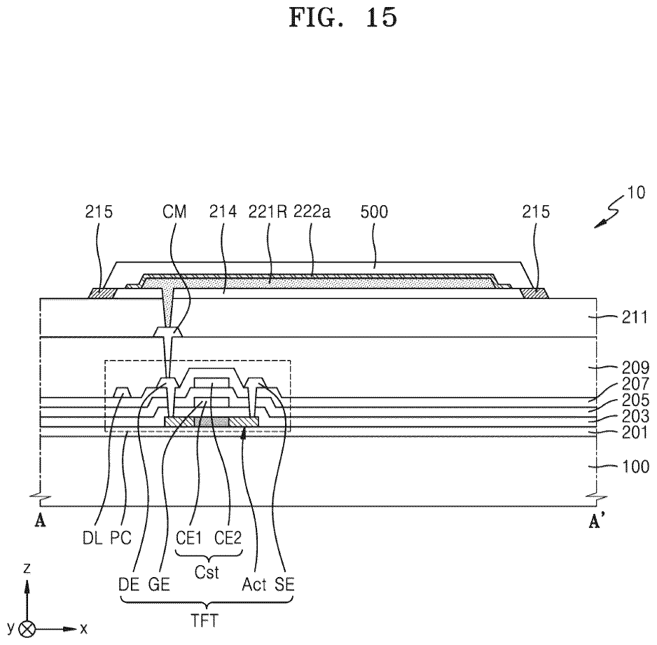

After the above operation, there may not be residual materials on the green pixel electrodes 221G and/or the blue pixel electrodes 221B. For example, one or more of the red pixels (subpixels) may have a substantially similar shape as shown in FIG. 15, and one or more of the green pixels (subpixels) and/or one or more of the blue pixels (subpixels) may have a substantially similar shape as shown in FIG. 11. Accordingly, after the same processes as described above with reference to FIGS. 12 to 15 are applied to the green pixels (subpixels), and after the same processes as described above with reference to FIGS. 12 to 15 are applied to the blue pixels (subpixels), one or more of the red pixels (subpixels), one or more of the green pixels (subpixels), and/or one or more of the blue pixels (subpixels) may have a substantially similar shape as shown in FIG. 15.

Thereafter, the sacrificial layers 500 may be removed, for example by using wet etching. In one or more embodiments, to minimize or reduce damage to the first intermediate layers 222a, the sacrificial layers 500 may be removed by using buffered oxide etchant (BOE), for example. In one or more embodiments, during the process, to remove residual moisture, moisture may be removed in a vacuum oven at a determined temperature (in a range of approximately 90° C. to approximately 100° C.). Thereafter, by forming the second intermediate layer 222b on the first intermediate layers 222a, for example using deposition, and then by forming the common electrode 223, for example using sputtering, an OLED, which is a display element 220, may be formed. In one or more embodiments, a subsequent process of forming the thin-film encapsulation layer 300 may be included in the method for manufacturing the display panel 10.

By arranging the first intermediate layer 222a including the emission layer through the abovementioned process, a reduced (or simplified) process for manufacturing the display apparatus may be achieved with as compared to manufacturing methods of forming the emission layer in a patterned shape via deposition using a fine metal mask.

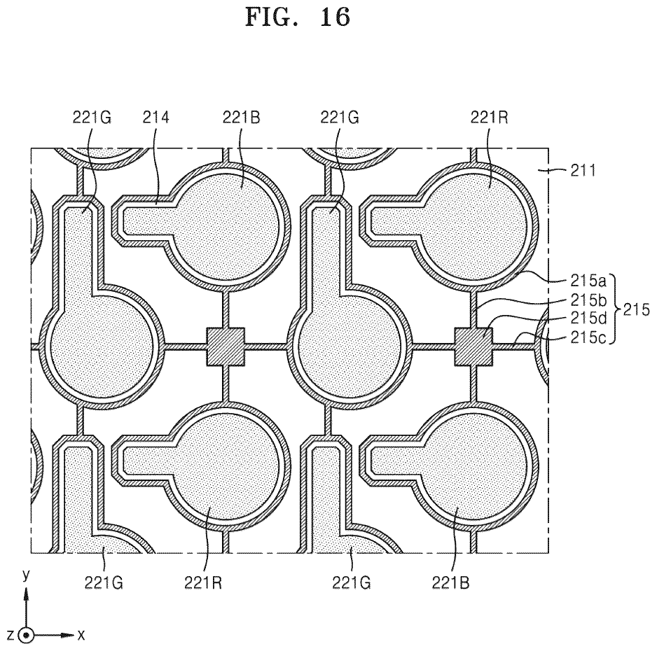

In one or more embodiments, the patterning wire 215 may be used as a bus electrode of the common electrode 223. For example, as described above with reference to FIGS. 8 and 9, by electrically connecting the common electrode 223 and the patterning wire 215 in the display area DA to each other, a voltage drop (IR drop) in the common electrode 223 may be substantially prevented, minimized, and/or reduced in the display area DA. FIG. 16 is a diagram illustrating a plan view of a region of the display panel 10, according to one or more embodiments. For example, the patterning wire 215 may have extension portions 215d that are arranged between the red pixel electrodes 221R, the green pixel electrodes 221G, and the blue pixel electrodes 221B and may have a larger width than the connection wires 215b. The common electrode 223 above the patterning wire 215 may be in contact with the extension portions 215d and may cause the common electrode 223 to be electrically connected to the patterning wire 215 having a substantially mesh shape in the display area DA. For example, a portion of the second intermediate layer 222b on the extension portions 215d may be removed.

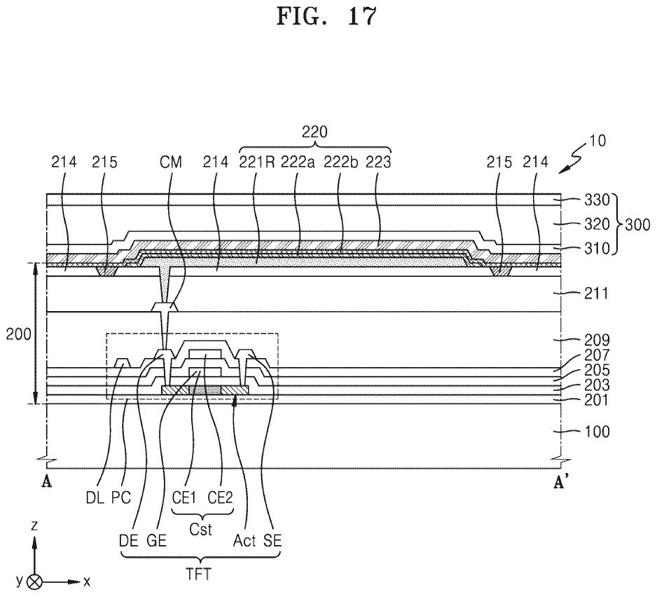

FIG. 17 is a diagram illustrating a cross-sectional view of a region of the display panel 10, according to one or more embodiments. As shown in FIG. 17, the support layer 214 may be configured to have indented portions of its surface (e.g., grooves) around (e.g., on opposite sides of) the red pixel electrode 221R, and the patterning wire 215 may be arranged in the indented portion of the support layer 214. For example, the support layer 214 and/or patterning wire 215 may have a substantially similar shape as described above with reference to FIG. 7. In one or more embodiments, an insulating layer including a substantially similar material as the support layer 214 may be arranged over the second organic insulating layer 211 and may fill a space between (or outside of) the patterning wire 215.

In one or more embodiments, as described above, when heat is generated in the patterning wire 215, the support layer 214 including an inorganic insulating material may not be deformed. In one or more embodiments, when the support layer 214 may be deformed, the degree of deformation may be minimized and/or reduced. For example, the second organic insulating layer 211, including an organic insulating material, may be partially deformed by the heat generated in the patterning wire 215. However, the second organic insulating layer 211 may have a thickness to function as a planarization layer, thereby preventing and/or reducing defects that may be caused by such heat related deformation.

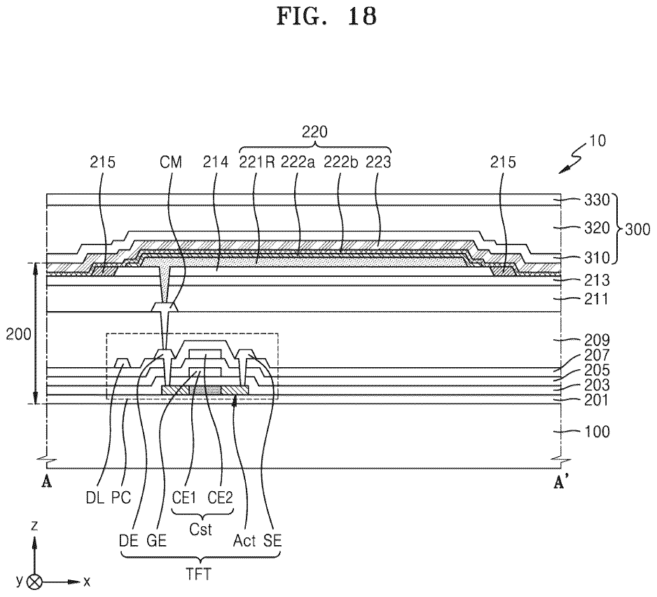

FIG. 18 is a diagram illustrating a cross-sectional view of a region of the display panel 10, according to one or more embodiments. An additional insulating layer 213, including an inorganic insulating material, such as silicon oxide, silicon nitride, silicon oxynitride, aluminum oxide, titanium oxide, tantalum oxide, hafnium oxide, and/or the like, may be formed on the second organic insulating layer 211. The support layer 214 and the patterning wire 215 may be arranged over the additional insulating layer 213. Therefore, during the manufacturing process, defects that may be caused by the heat generated in the patterning wire 215 may be prevented, minimized, and/or reduced.

As described above, the disclosure has been described with reference to the one or more embodiments shown in the accompanying drawings, but should be considered in a descriptive sense only. Those of ordinary skill in the art will understand that various modifications and equivalent embodiments may be made therefrom. Therefore, the true technical scope of protection of the disclosure should be defined by the technical spirit of the appended claims.

According to the one or more embodiments as described above, a display panel having a simplified manufacturing process and an electronic apparatus including the display panel may be implemented. However, the scope of the disclosure is not limited by the above effects.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate;
a planarization layer above the substrate;
a support layer above the planarization layer, and having an isolated shape in plan view;
a patterning wire above the planarization layer, and contacting a side surface of the support layer;
a pixel electrode above the support layer, and having an isolated shape in plan view; and
a first intermediate layer separated from the patterning wire, and covering the pixel electrode.

2. The display panel of claim 1, wherein the patterning wire surrounds the support layer in plan view.

3. The display panel of claim 1, wherein an edge of the first intermediate layer contacts an upper surface of the support layer outside the pixel electrode in plan view.

4. The display panel of claim 1, wherein the first intermediate layer is configured to be deformed by heat.

5. The display panel of claim 1, further comprising:
a second intermediate layer above the first intermediate layer, the patterning wire, and the planarization layer; and
a common electrode above the second intermediate layer.

6. The display panel of claim 5, wherein the first intermediate layer comprises a hole transport layer and an emission layer, and
wherein the second intermediate layer comprises an electron transport layer.

7. The display panel of claim 5, wherein the patterning wire is electrically connected to the common electrode.

8. The display panel of claim 1, wherein a resistance of the patterning wire is greater than a resistance of the pixel electrode.

9. The display panel of claim 1, wherein the support layer comprises an inorganic insulating material.

10. A display panel comprising:
a substrate;
a planarization layer above the substrate;
support layers spaced apart from each other above the planarization layer, and having an isolated shape in plan view;
a patterning wire above the planarization layer, and contacting one or more side surfaces of the support layers;
pixel electrodes respectively above the support layers, and having an isolated shape in plan view; and
first intermediate layers apart from the patterning wire, and respectively above the pixel electrodes.

11. The display panel of claim 10, wherein the patterning wire surrounds one or more of the support layers in plan view.

12. The display panel of claim 11, wherein the patterning wire comprises:
surrounding wires respectively surrounding the support layers; and
connection wires electrically connecting the surrounding wires.

13. The display panel of claim 12, wherein the surrounding wires are integral with the connection wires.

14. The display panel of claim 10, wherein edges of the first intermediate layers respectively contact the support layers.

15. The display panel of claim 10, wherein the first intermediate layers are configured to be deformed by heat.

16. The display panel of claim 10, further comprising:
a second intermediate layer above the first intermediate layers, the patterning wire, and the planarization layer, and corresponding to the pixel electrodes; and
a common electrode above the second intermediate layer, and corresponding to the pixel electrodes.

17. The display panel of claim 16, wherein one or more of the first intermediate layers comprises a hole transport layer and an emission layer, and
wherein the second intermediate layer comprises an electron transport layer.

18. The display panel of claim 16, wherein the patterning wire is electrically connected to the common electrode.

19. The display panel of claim 10, wherein a resistance of the patterning wire is greater than a resistance of one or more of the pixel electrodes.

20. An electronic apparatus comprising:
a processor; and
a display panel configured to be controlled by the processor, the display panel comprising:
a substrate;
a planarization layer above the substrate;
a support layer above the planarization layer;
a patterning wire above the planarization layer and configured to contact the support layer;
a pixel electrode above the support layer; and
a first intermediate layer above the pixel electrode.
